(19) United States
(12) Patent Application Publication
(10) Pub. No.: US 2024/0306296 A1
(43) Pub. Date: Sep. 12, 2024

(54) WIRING SUBSTRATE

(71) Applicant: IBIDEN CO., LTD., Ogaki (JP)

(72) Inventors: Toshiki FURUTANI, Ogaki (JP); Masashi KUWABARA, Ibi-gun (JP); Jun SAKAI, Ogaki (JP); Takuya INISHI, Ogaki (JP)

(73) Assignee: IBIDEN CO., LTD., Ogaki (JP)

(21) Appl. No.: 18/599,671

(22) Filed: Mar. 8, 2024

(30) Foreign Application Priority Data
Mar. 9, 2023 (JP) 2023-036686

(51) Int. Cl. H05K 1/11; H05K 1/03; H05K 3/16

(52) U.S. Cl. CPC H05K 1/115; H05K 1/0306; H05K 3/16; H05K 2201/0209; H05K 2201/0245; H05K 2201/0323; H05K 2201/09536; H05K 2203/0361

(57) ABSTRACT

A wiring substrate includes a core substrate including a glass substrate and a through-hole conductor formed in the glass substrate, a resin insulating layer formed on the core substrate and including resin and inorganic particles, a conductor layer formed on the insulating layer and including a seed layer and an electrolytic plating layer, and a via conductor formed in the insulating layer such that the via conductor is electrically connected to the through-hole conductor formed in the glass substrate and includes the seed layer and electrolytic plating layer extending from the conductor layer. The conductor layer and the via conductor are formed such that the seed layer is formed by sputtering, and the resin insulating layer has an opening in which the via conductor is formed such that the inorganic particles include first particles forming an inner wall surface in the opening and second particles embedded in the insulating layer.

### CROSS-REFERENCE TO RELATED APPLICATIONS

The present application is based upon and claims the benefit of priority to Japanese Patent Application No. 2023-036686, filed Mar. 9, 2023, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2015-133473 describes a multilayer substrate having a core formed of a glass material. The entire contents of this publication are incorporated herein by reference.

### SUMMARY OF THE INVENTION

According to one aspect of the present invention, a wiring substrate includes a core substrate including a glass substrate and a through-hole conductor formed in the glass substrate, a resin insulating layer formed on the core substrate and including resin and inorganic particles, a conductor layer formed on a surface of the resin insulating layer and including a seed layer and an electrolytic plating layer formed on the seed layer, and a via conductor formed in the resin insulating layer such that the via conductor is electrically connected to the through-hole conductor formed in the glass substrate of the core substrate and includes the seed layer and electrolytic plating layer extending from the conductor layer. The conductor layer and the via conductor are formed such that the seed layer is formed by sputtering, and the resin insulating layer has an opening in which the via conductor is formed such that the inorganic particles include first particles forming an inner wall surface in the opening and second particles embedded in the resin insulating layer having shapes that are different from shapes of the first particles.

According to another aspect of the present invention, a method for manufacturing a wiring substrate includes forming a core substrate including a glass substrate and a through-hole conductor formed in the glass substrate, forming a resin insulating layer on the core substrate such that the resin insulating layer includes resin and inorganic particles, forming a conductor layer on a surface of the resin insulating layer such that the conductor layer includes a seed layer and an electrolytic plating layer formed on the seed layer, and forming a via conductor in the resin insulating layer such that the via conductor electrically connects to the through-hole conductor formed in the glass substrate of the core substrate and includes the seed layer and electrolytic plating layer extending from the conductor layer. The forming of the conductor layer and the forming of the via conductor include forming the seed layer by sputtering, the forming of the resin insulating layer includes forming an opening in which the via conductor is formed such that the inorganic particles include first particles forming an inner wall surface in the opening and second particles embedded in the resin insulating layer having shapes that are different from shapes of the first particles, and the forming of the opening includes forming the inorganic particles having protruding portions protruding from the resin in the opening, and removing the protruding portions of the inorganic particles such that the first particles are formed.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view schematically illustrating a wiring substrate according to an embodiment of the present invention;

FIG. 2 is an enlarged cross-sectional view schematically illustrating a part of a wiring substrate according to an embodiment of the present invention;

FIG. 3A is a cross-sectional view schematically illustrating a method for manufacturing a wiring substrate according to an embodiment of the present invention;

FIG. 3B is a cross-sectional view schematically illustrating a method for manufacturing a wiring substrate according to an embodiment of the present invention;

FIG. 3C is a cross-sectional view schematically illustrating a method for manufacturing a wiring substrate according to an embodiment of the present invention;

FIG. 3D is a cross-sectional view schematically illustrating a method for manufacturing a wiring substrate according to an embodiment of the present invention;

FIG. 3E is a cross-sectional view schematically illustrating a method for manufacturing a wiring substrate according to an embodiment of the present invention;

FIG. 3F is a cross-sectional view schematically illustrating a method for manufacturing a wiring substrate according to an embodiment of the present invention;

FIG. 3G is a cross-sectional view schematically illustrating a method for manufacturing a wiring substrate according to an embodiment of the present invention;

FIG. 3H is a cross-sectional view schematically illustrating a method for manufacturing a wiring substrate according to an embodiment of the present invention;

FIG. 3I is a cross-sectional view schematically illustrating a method for manufacturing a wiring substrate according to an embodiment of the present invention;

FIG. 3J is a cross-sectional view schematically illustrating a method for manufacturing a wiring substrate according to an embodiment of the present invention;

FIG. 3K is a cross-sectional view schematically illustrating a method for manufacturing a wiring substrate according to an embodiment of the present invention;

FIG. 4 is an enlarged cross-sectional view schematically illustrating a method for manufacturing a wiring substrate of a first alternative example according to an embodiment of the present invention;

FIG. 5 is a cross-sectional view schematically illustrating a method for manufacturing a wiring substrate of a modified example according to an embodiment of the present invention; and

FIG. 6 is a cross-sectional view schematically illustrating a method for manufacturing a wiring substrate of a modified example according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

### Embodiment

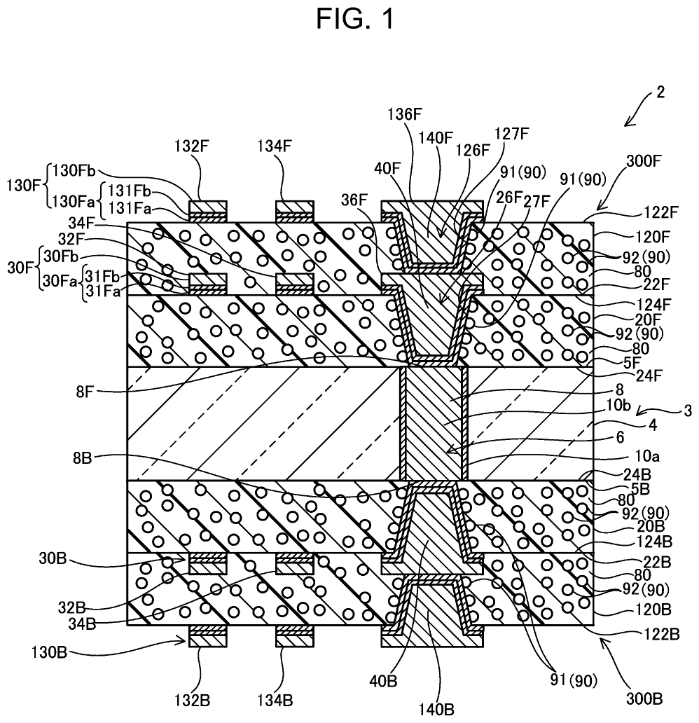

FIG. 1 is a cross-sectional view illustrating a wiring substrate 2 according to an embodiment of the present invention. As illustrated in FIG. 1, the wiring substrate 2 includes a core substrate 3, a front side build-up layer (300F), and a back side build-up layer (300B).

The core substrate 3 includes a substrate 4, through holes 6, and through-hole conductors 8. The substrate 4 has a front surface (5F) and a back surface (5B) on the opposite side with respect to the front surface (5F). The substrate 4 is formed of glass. The through holes 6 penetrate the substrate 4. The through holes 6 each have a substantially cylindrical shape. The through holes 6 each have a substantially constant diameter. It is also possible that the through holes 6 each have a substantially truncated cone shape. It is also possible that the through holes 6 each have a shape obtained by connecting two substantially conical shapes. The two cones are a front surface side cone and a back surface side cone. A bottom surface of the front surface side cone is positioned on the front surface (5F), and a bottom surface of the back surface side cone is positioned on the back surface (5B). In this case, a side surface of each of the through holes 6 is formed of a surface tapering from the front surface (5F) toward the back surface (5B) and a surface tapering from the back surface (5B) toward the front surface (5F).

The through-hole conductors 8 are respectively formed in the through holes 6. The through-hole conductors 8 are mainly formed of copper. The through-hole conductors 8 include a seed layer (10a) formed on inner wall surfaces of the through holes 6 and an electrolytic plating layer (10b) formed on the seed layer (10a). The electrolytic plating layer (10b) fills the through holes 6. The seed layer (10a) is formed by electroless plating. The through-hole conductors 8 each have an upper end (8F) and a lower end (8B). A surface of the upper end (8F) and the front surface (5F) form substantially the same flat surface. A surface of the lower end (8B) and the back surface (5B) form substantially the same flat surface. The upper end (8F) is exposed from the front surface (5F). The lower end (8B) is exposed from the back surface (5B).

The front side build-up layer (300F) is formed on the front surface (5F) of the substrate 4. The front side build-up layer (300F) includes front side resin insulating layers, front side conductor layers, and front side via conductors that penetrate the front side resin insulating layers. The front side conductor layers and the front side via conductors are electrically connected to the through-hole conductors 8. The front side resin insulating layers and the front side conductor layers are alternately laminated. The front side resin insulating layers in FIG. 1 are a first resin insulating layer (20F) and a second resin insulating layer (120F). The front side conductor layers are a first conductor layer (30F) and a second conductor layer (130F). The front side via conductors are first via conductors (40F) and second via conductors (140F).

The first resin insulating layer (20F) has a first surface (22F) and a second surface (24F) on the opposite side with respect to the first surface (22F). The first resin insulating layer (20F) is formed on the front surface (5F) of the substrate 4 with the second surface (24F) facing the front surface (5F). In the example of FIG. 1, the second surface (24F) is in contact with the front surface (5F). The second surface (24F) is in contact with a part of the upper end (8F). No conductor circuit exists between the front surface (5F) and the second surface (24F). No conductor circuit is formed on the front surface (5F). The first resin insulating layer (20F) has first openings (26F) that respectively reach the upper ends (8F) of the through-hole conductors 8. The first openings (26F) each have an opening (top opening) on the first surface (22F) and an opening (bottom opening) on the second surface (24F). The top opening and the bottom opening each have a substantially circular shape. The bottom opening can expose the upper end (8F) and the front surface (5F) at the same time. In this case, the front surface (5F) around the upper end (8F) is exposed. It is also possible that the bottom opening exposes a part of the upper end (8F) and the front surface (5F) around the part (first example). It is also possible that the bottom opening exposes the entire upper end (8F) and the front surface (5F) around the upper end (8F) (second example). As illustrated in FIG. 1, the bottom opening can expose only the upper end (8F) (third example). Two examples among the first example, the second example and the third example may be mixed. All of the first example, the second example and the third example may be mixed. It is preferable that the first example and the third example are mixed. In this case, the upper ends (8F) of some of the through-hole conductors 8 are exposed by the openings of the first example, and the upper ends (8F) of the remaining through-hole conductors are exposed by the openings of the third example. The first resin insulating layer (20F) is formed of a resin 80 and a large number of inorganic particles 90 dispersed in the resin 80. The resin 80 is an epoxy resin. Examples of the resin include a thermosetting resin and a photocurable resin. The inorganic particles 90 are glass particles. It is also possible that the inorganic particles 90 are alumina particles. A content of the inorganic particles 90 in the first resin insulating layer (20F) is 75 wt % or more.

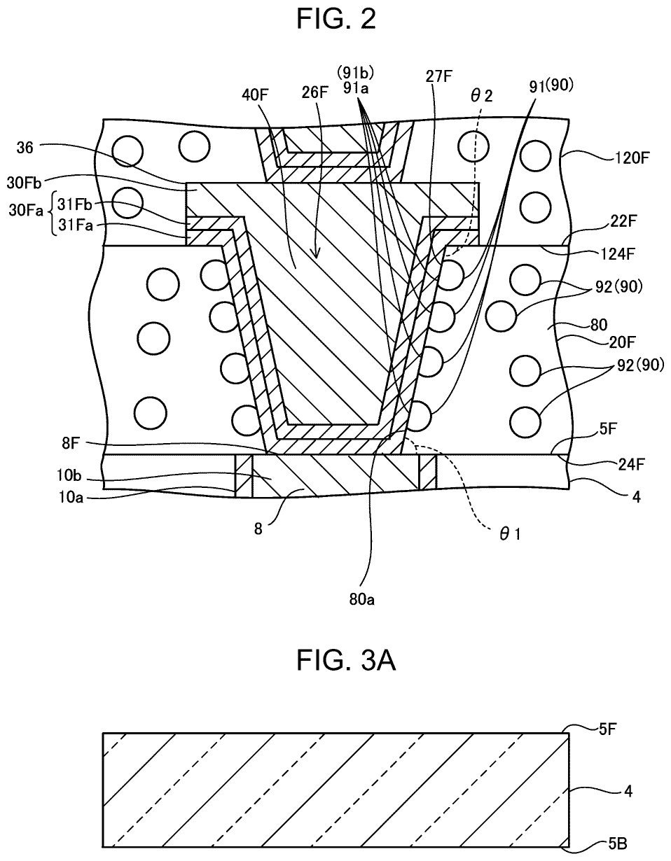

As illustrated in FIGS. 1 and 2, the inorganic particles 90 include first inorganic particles 91 forming an inner wall surface (27F) of each of the first openings (26F) and second inorganic particles 92 embedded in the resin 80. The second inorganic particles 92 each have a spherical shape. The first inorganic particles 91 each have a shape obtained by cutting a sphere along a flat surface. The first inorganic particles 91 each have a shape obtained by cutting a second inorganic particle 92 along a flat surface. The first inorganic particles 91 and the second inorganic particles 92 are different in shape.

The first surface (22F) of the first resin insulating layer (20F) is formed only of the resin 80. No inorganic particles 90 (second inorganic particles 92) are exposed from the first surface (22F). The first surface (22F) does not include surfaces of the second inorganic particles 92. No unevenness is formed on the first surface (22F) of the first resin insulating layer (20F). The first surface (22F) is not roughened. The first surface (22F) is formed smooth.

As illustrated in FIG. 2, the inner wall surface (27F) of each of the first openings (26F) is formed of the resin 80 and the first inorganic particles 91. The first inorganic particles 91 each have a flat part (91a). The flat parts (91a) form the inner wall surface (27F). The inner wall surface (27F) is formed of the resin 80 and the flat parts (91a). The flat parts (91a) and a surface of the resin 80 that forms the inner wall surface (27F) form substantially a common surface. No unevenness is formed on the resin 80 that forms the inner wall surface (27F). The surface of the resin 80 that forms the inner wall surface (27F) is smooth. No unevenness is formed on exposed surfaces (91b) of the flat parts (91a) (surfaces that form the inner wall surface (27F)). The exposed surfaces (91b) of the flat parts (91a) are smooth. The inner wall surface (27F) is formed smooth. The inner wall surface (27F) has an arithmetic mean roughness (Ra) of 1.0μ m or less.

The flat parts (91a) of the first inorganic particles 91 substantially coincide with a surface obtained by extending the surface (80a) of the resin 80 formed around the first inorganic particles 91 (a surface that forms the inner wall surface (27F)). The flat parts (91a) drawn with substantially straight lines in FIGS. 1 and 2 each mean a flat surface. In the cross sections illustrated in FIGS. 1 and 2, the flat parts (91a) are each a flat surface. It is also possible that the flat parts (91a) are not each a perfect flat surface. The flat parts (91a) are each substantially a flat surface and are each substantially a smooth surface. As illustrated in FIG. 2, the inner wall surface (27F) of each of the first openings (26F) is inclined. An angle (inclination angle) (θ1) between the front surface (5F) of the substrate 4 and the inner wall surface (27F) is 70 degrees or more and 85 degrees or less. An angle (inclination angle) (θ2) between the first surface (22F) of the first resin insulating layer (20F) and the inner wall surface (27F) is 95 degrees or more and 110 degrees or less.

In the cross-sections illustrated in FIGS. 1 and 2, the first openings (26F) are illustrated to each have a substantially inverted trapezoidal shape. However, the actual first openings (26F) each have a substantially inverted truncated cone shape. Therefore, the actual inner wall surface (side wall) (27F) of each of the first openings (26F) is a substantially curved surface. That is, the common surface formed by the flat parts (91a) and the resin 80 includes the inner wall surface (side wall) (27F) formed as a substantially curved surface.

As illustrated in FIG. 1, the first conductor layer (30F) is formed on the first surface (22F) of the first resin insulating layer (20F). The first conductor layer (30F) includes a first signal wiring (32F), a second signal wiring (34F), and lands (36F). Although not illustrated in the drawings, the first conductor layer (30F) also includes conductor circuits other than the first signal wiring (32F), the second signal wiring (34F), and the lands (36F). The first signal wiring (32F) and the second signal wiring (34F) form a pair wiring. The first conductor layer (30F) is mainly formed of copper. The first conductor layer (30F) is formed of a seed layer (30Fa) and an electrolytic plating layer (30Fb) on the seed layer (30Fa). The seed layer (30Fa) is formed by sputtering. The seed layer (30Fa) is formed of a first layer (31Fa) on the first surface (22F) and a second layer (31Fb) on the first layer (31Fa). The first layer (31Fa) is in contact with the first surface (22F). The second layer (31Fb) is not essential.

The first layer (31Fa) is formed of an alloy containing copper, aluminum, and a specific metal. Examples of the specific metal include nickel, zinc, gallium, silicon, and magnesium. The alloy preferably contains one type of specific metal, or two types of specific metals, or three types of specific metals. A content of aluminum in the alloy is 1.0 at % or more and 15.0 at % or less. An example of the specific metal is silicon. A content of the specific metal in the alloy is 0.5 at % or more and 10.0 at % or less. The first layer (31Fa) may contain impurities. Examples of the impurities include oxygen and carbon. The first layer (31Fa) can contain oxygen or carbon. The first layer (31Fa) can contain oxygen and carbon. In the embodiment, the alloy further contains carbon. A content of carbon in the alloy is 50 ppm or less. The alloy further contains oxygen. A content of oxygen in the alloy is 100 ppm or less. The values of the contents of the elements described above are examples. Among the elements forming the first layer (31Fa), copper has the largest content. The content of aluminum is the next largest. The content of the specific metal is less than the content of aluminum. Therefore, copper is a primary metal, aluminum is a first secondary metal, and the specific metal is a second secondary metal. A content of the impurities is smaller than the content of the specific metal.

The second layer (31Fb) is formed of copper. A content of copper forming the second layer (31Fb) is 99.9 at % or more. The content of copper in the second layer (31Fb) is preferably 99.95 at % or more. The electrolytic plating layer (30Fb) is formed of copper. A content of copper forming the electrolytic plating layer (30Fb) is 99.9 at % or more. The content of copper in the electrolytic plating layer (30Fb) is preferably 99.95 at % or more.

The first resin insulating layer (20F) is formed on the glass substrate 4. Since glass is excellent in flatness, the first surface (22F) of the first resin insulating layer (20F) is also excellent in flatness. When no conductive circuit is formed between the front surface (5F) and the first resin insulating layer (20F), the first surface (22F) can follow the front surface (5F). The first surface (22F) can have similar flatness as the front surface (5F). In the embodiment, fine wirings can be formed on the first surface (22F). For example, the first conductor layer (30F) can have wirings having widths of 1.5μ m or more and 3.5μ m or less. A width of a space between adjacent wirings is 1.5μ m or more and 3.5μ m or less.

The first via conductors (40F) are respectively formed in the first openings (26F). The first via conductors (40F) electrically connect the through-hole conductors 8 to the first conductor layer (30F). The first via conductors (40F) electrically connect the through-hole conductors 8 to the lands (36F) of the first via conductor (40F). The first via conductors (40F) are formed of a seed layer (30Fa) and an electrolytic plating layer (30Fb) on the seed layer (30Fa). The seed layer (30Fa) forming the first via conductors (40F) and the seed layer (30Fa) forming the first conductor layer (30F) are common. The electrolytic plating layer (30Fb) forming the first via conductors (40F) and the electrolytic plating layer (30Fb) forming the first conductor layer (30F) are common. The seed layer (30Fa) forming the first via conductors (40F) is formed of a first layer (31Fa), which is formed on the inner wall surfaces (27F) of the first openings (26F) and on the upper ends (8F) of the through-hole conductors 8 exposed from the first openings (26F), and a second layer (31Fb) on the first layer (31Fa). In FIG. 1, the first via conductors (40F) are respectively connected to the upper ends (8F). The first layer (31Fa) is in contact with the upper ends (8F) of the through-hole conductors 8 and the inner wall surfaces (27F). The first via conductors (40F) are respectively directly formed on the upper ends (8F).

When the openings for the via conductors expose the front surface (5F), the first layer (31Fa) is in contact with the glass substrate 4. The openings of the first example and the openings of the second example expose the front surface (5F). Further, the openings of the first example and the openings of the second example expose the upper ends (8F). Since the first layer (31Fa) contains aluminum and glass contains oxygen, it is thought that bonding strength between the first layer (31Fa) and the substrate 4 is increased. Further, when the first layer (31Fa) contains silicon, the first layer (31Fa) and the substrate 4 contain the same element (silicon). It is thought that the bonding strength between the first layer (31Fa) and the substrate 4 is further increased. When a part of the seed layer forming the via conductors is in contact with the glass substrate 4, the via conductors are unlikely to peel off from the through-hole conductors 8 even when the wiring substrate 2 is subjected to a thermal shock. The seed layer (for example, the first layer (31Fa)) forming the via conductors that is in contact with the upper ends (8F) is preferably in contact with both the upper ends (8F) and the front surface (5F). Similarly, the seed layer (for example, the first layer) forming the via conductors that is in contact with the lower ends (8B) is preferably in contact with both the lower ends (8B) and the back surface (5B). When an adhesive layer for bonding a resin insulating layer such as the first resin insulating layer (20F) and the substrate 4 is formed between the front surface (5F) and the second surface (24F), the adhesive layer may be a part of the resin insulating layer. The adhesive layer is included in the resin insulating layer. The adhesive layer includes an organic adhesive layer and an inorganic adhesive layer. The adhesive layer is formed of an insulating material.

The second resin insulating layer (120F) is formed on the first surface (22F) of the first resin insulating layer (20F) and on the first conductor layer (30F). The first conductor layer (30F) is formed between the second resin insulating layer (120F) and the first resin insulating layer (20F). The second resin insulating layer (120F) has a first surface (122F) and a second surface (124F) on the opposite side with respect to the first surface (122F).

The second surface (124F) of the second resin insulating layer (120F) faces the first conductor layer (30F). Similar to the first resin insulating layer (20F), the second resin insulating layer (120F) is formed of a resin 80 and inorganic particles 90 (first inorganic particles 91 and second inorganic particles 92). Therefore, the material of the second resin insulating layer (120F) is similar to the material of the first resin insulating layer (20F). The first surface (122F) of the second resin insulating layer (120F) is similar to the first surface (22F) of the first resin insulating layer (20F).

The second resin insulating layer (120F) has second openings (126F) that expose the first conductor layer (30F). The second openings (126F) respectively expose the lands (36F). The second openings (126F) each have an inner wall surface (127F). The first openings (26F) and the second openings (126F) are similar. Therefore, the inner wall surface (27F) of each of the first openings (26F) and the inner wall surface (127F) of each of the second openings (126F) are similar.

The second conductor layer (130F) is formed on the first surface (122F) of the second resin insulating layer (120F). The second conductor layer (130F) includes a first signal wiring (132F), a second signal wiring (134F), and lands (136F). Although not illustrated in the drawings, the second conductor layer (130F) also includes conductor circuits other than the first signal wiring (132F), the second signal wiring (134F), and the lands (136F). The first signal wiring (132F) and the second signal wiring (134F) form a pair wiring. The second conductor layer (130F) and the first conductor layer (30F) are similar. Therefore, the second conductor layer (130F) is formed of a seed layer (130Fa) and an electrolytic plating layer (130Fb) on the seed layer (130Fa). The seed layer (130Fa) is formed of a first layer (131Fa) and a second layer (131Fb) on the first layer (131Fa). The first layer (131Fa) forming the second conductor layer (130F) is similar to the first layer (31Fa) forming the first conductor layer (30F). The second layer (131Fb) forming the second conductor layer (130F) is similar to the second layer (31Fb) forming the first conductor layer (30F). The electrolytic plating layer (130Fb) forming the second conductor layer (130F) is similar to the electrolytic plating layer (30Fb) forming the first conductor layer (30F).

The second via conductors (140F) are respectively formed in the second openings (126F). The second via conductors (140F) electrically connect the first conductor layer (30F) and the second conductor layer (130F). In FIG. 1, the second via conductors (140F) respectively electrically connect the lands (36F) to the lands (136F). The second via conductors (140F) and the first via conductors (40F) are similar. Therefore, the second via conductors (140F) are formed of a seed layer (130Fa) and an electrolytic plating layer (130Fb) on the seed layer (130Fa). The seed layer (130Fa) is formed of a first layer (131Fa) and a second layer (131Fb) on the first layer (131Fa). The first layer (131Fa) forming the second via conductors (140F) and the first layer (131Fa) forming the second conductor layer (130F) are common. The second layer (131Fb) forming the second via conductors (140F) and the second layer (131Fb) forming the second conductor layer (130F) are common. The electrolytic plating layer (130Fb) forming the second via conductors (140F) and the electrolytic plating layer (130Fb) forming the second conductor layer (130F) are common.

The back side build-up layer (300B) includes back side resin insulating layers, back side conductor layers, and back side via conductors that penetrate the back side resin insulating layers. The back side resin insulating layers and the back side conductor layers are alternately laminated. The back side conductor layers and the back side via conductors are electrically connected to the through-hole conductors 8. The back side resin insulating layers in FIG. 1 are a first resin insulating layer (20B) having a first surface (22B) and a second surface (24B) and a second resin insulating layer (120B) having a first surface (122B) and a second surface (124B). The back side conductor layers are a first conductor layer (30B) and a second conductor layer (130B). The first conductor layer (30B) and the second conductor layer (130B) include first signal wirings (32B, 132B) and second signal wirings (34B, 134B). The back side via conductors are first via conductors (40B) and second via conductors (140B).

The front side build-up layer (300F) and the back side build-up layer (300B) are similar. Therefore, the front side resin insulating layers forming the front side build-up layer (300F) and the back side resin insulating layers forming the back side build-up layer (300B) are similar. The back side resin insulating layers are each formed of a resin 80 and inorganic particles 90. The back side resin insulating layers contain the first inorganic 91 and the second inorganic particles 92. The first surface of each of the resin insulating layers is formed only of the resin. The front side conductor layers and the back side conductor layers are similar. The openings for the front side via conductors and the openings for the back side via conductors are similar. The inner wall surface of each of the openings for the via conductors is formed of the surface (exposed surface) (80a) of the resin 80 and the exposed surfaces (91b) of the inorganic particles. The front side via conductors and the back side via conductors are similar.

Although not illustrated in the drawings, each side of the wiring substrate 2 has a length of 50 mm or more. The length of each side is preferably 100 mm or more. The length of each side is 250 mm or less. A length of a signal wiring formed according to the embodiment is 5 mm or more. The length of the signal wiring may be 10 mm or more and 20 mm or less.

### Method for Manufacturing Wiring Substrate

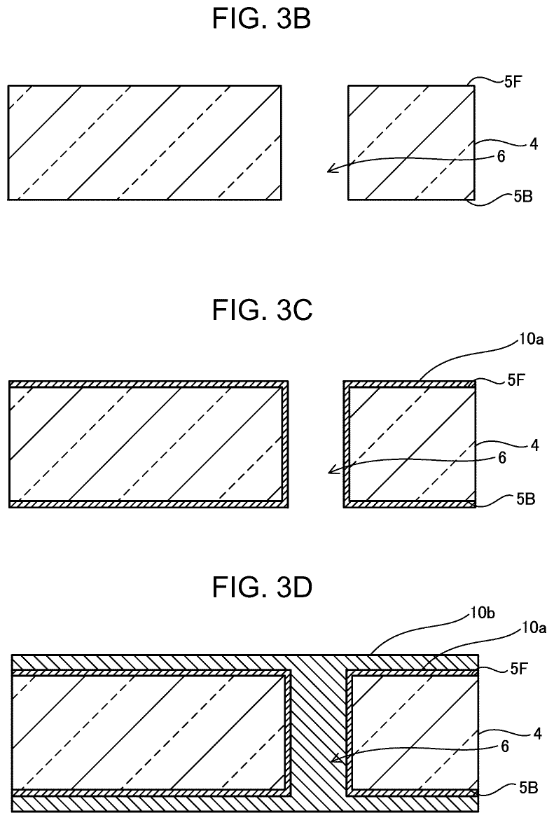

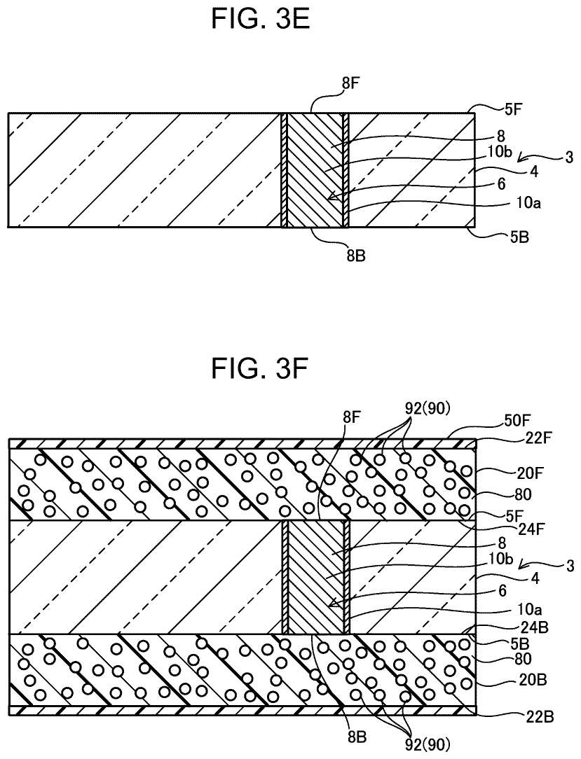

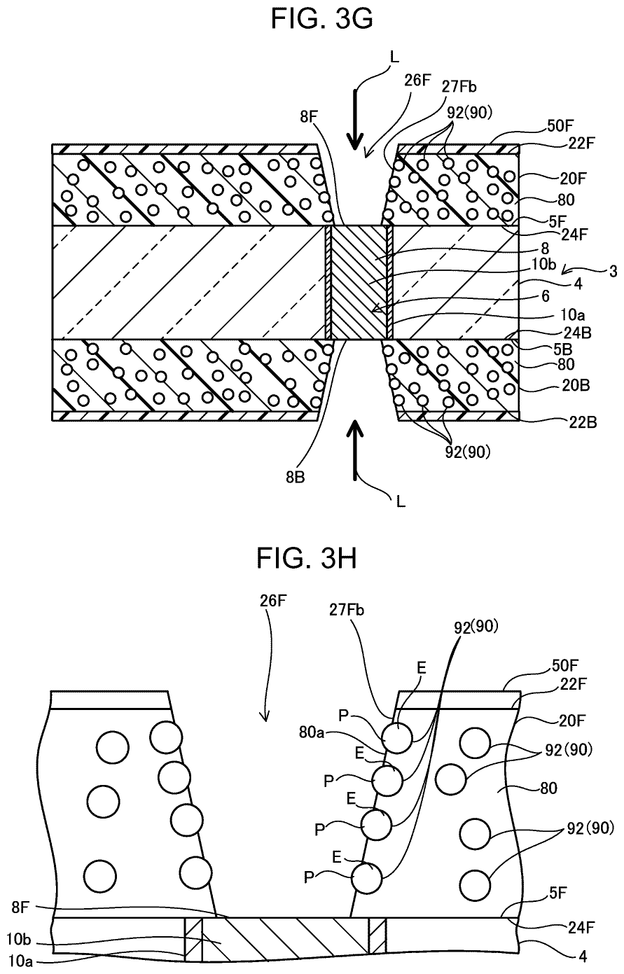

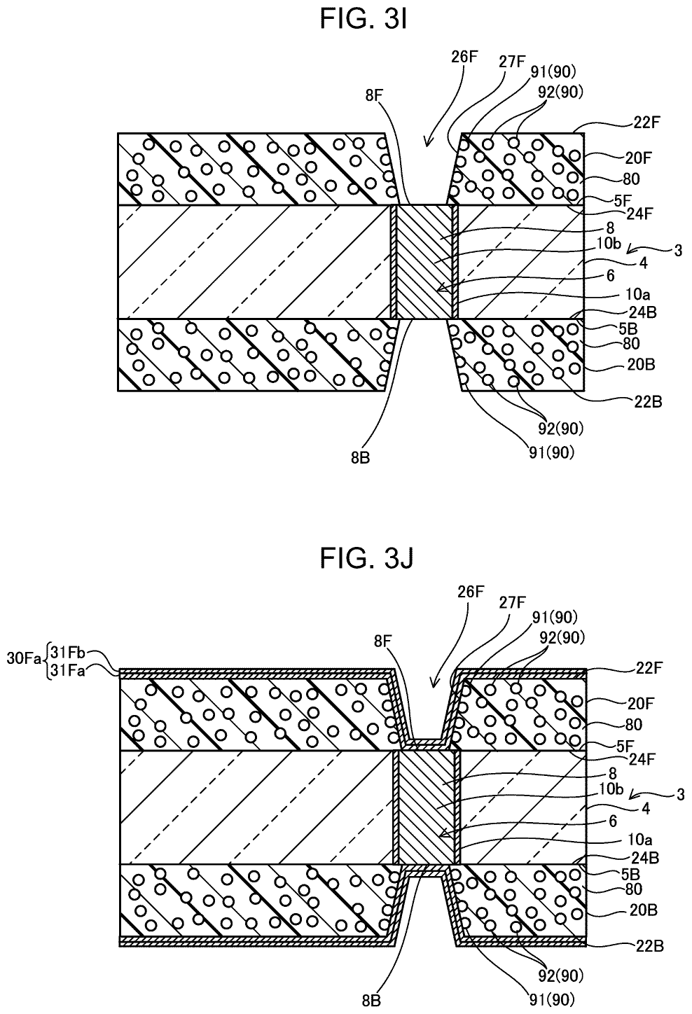

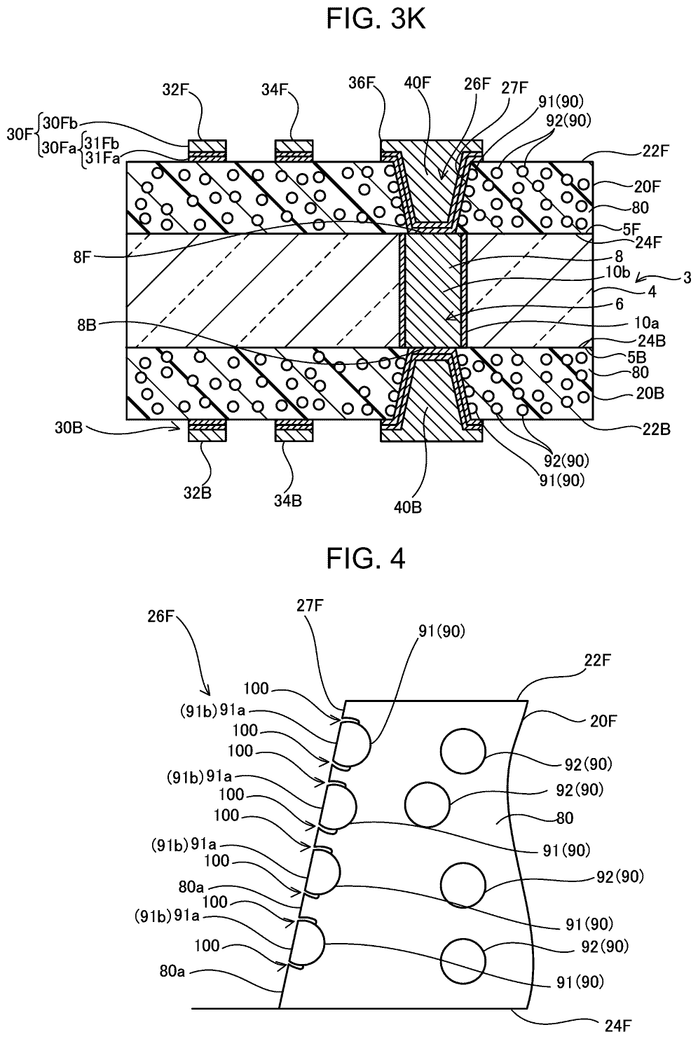

FIGS. 3A-3K illustrate a method for manufacturing the wiring substrate 2 of the embodiment. FIGS. 3A-3G and 3I-3K are cross-sectional views. FIG. 3H is an enlarged cross-sectional view. FIG. 3A illustrates the glass substrate 4. The substrate 4 has the front surface (5F) and the back surface (5B). As illustrated in FIG. 3B, the through holes 6 each extending from the front surface (5F) to the back surface (5B) are formed. The through holes 6 penetrate the substrate 4. Laser is irradiated from the front surface (5F) side of the substrate 4. After that, the substrate 4 is immersed in a hydrofluoric acid. The through holes 6 are formed.

As illustrated in FIG. 3C, the seed layer (10a) is formed. The seed layer (10a) is formed by electroless plating. The seed layer (10a) is formed on the inner wall surfaces of the through holes 6, on the front surface (5F), and on the back surface (5B).

As illustrated in FIG. 3D, the electrolytic plating layer (10b) is formed. The electrolytic plating layer (10b) is formed on the seed layer (10a). The electrolytic plating layer (10b) fills the through holes 6.

As illustrated in FIG. 3E, the electrolytic plating layer (10b) and the seed layer (10a) on the front surface (5F) are removed by polishing. The electrolytic plating layer (10b) and the seed layer (10a) on the back surface (5B) are removed by polishing. The front surface (5F) and the back surface (5B) of the substrate 4 are exposed. The through-hole conductors 8 are formed by the seed layer (10a) on the inner wall surfaces of the through holes 6 and the electrolytic plating layer (10b) on the seed layer (10a). The upper ends (8F) of the through-hole conductors 8 are exposed from the front surface (5F). The lower ends (8B) of the through-hole conductors 8 are exposed from the back surface (5B). Surfaces forming the upper ends (8F) and the front surface (5F) form the same flat surface. Surfaces forming the lower ends (8B) and the back surface (5B) form the same flat surface. The core substrate 3 (FIG. 1) is formed. The core substrate 3 in FIG. 1 has no conductor circuit on the front surface (5F). The core substrate 3 in FIG. 1 has no conductor circuit on the back surface (5B).

The front side build-up layer (300F) and the back side build-up layer (300B) are formed on core substrate 3 using similar methods. The method for forming the front side build-up layer (300F) is described below. The back side build-up layer (300B) is also depicted in the drawings.

As illustrated in FIG. 3F, the first resin insulating layer (20F) and a protective film (50F) are formed on the front surface (5F) of the substrate 4 and on the upper ends (8F). The second surface (24F) of the first resin insulating layer (20F) faces the front surface (5F) of the substrate 4. The protective film (50F) is formed on the first surface (22F) of the first resin insulating layer (20F). The first surface (22F) of the first resin insulating layer (20F) is formed only of the resin 80. No inorganic particles 90 are exposed from the first surface (22F). The first surface (22F) does not include surfaces of the inorganic particles 90. No unevenness is formed on the first surface (22F) of the first resin insulating layer (20F). The first resin insulating layer (20F) is formed on a flat surface formed by the front surface (5F) and the upper ends (8F). Therefore, the first surface (22F) is formed as a substantially flat surface. The front surface (5F) and the first surface (22F) are substantially parallel.

As illustrated in FIG. 3G, laser (L) is irradiated from above the protective film (50F). The laser (L) penetrates the protective film (50F) and the first resin insulating layer (20F) at the same time. The first openings (26F) for the via conductors reaching the upper ends (8F) of the through-hole conductors 8 are formed. The laser (L) is, for example, UV laser, or CO₂ laser. The upper ends (8F) of the through-hole conductors 8 are exposed from the first openings (26F). When the first openings (26F) are formed, the first surface (22F) is covered by the protective film (50F). When the first openings (26F) are formed, even when the resin scatters, adherence of the resin to the first surface (22F) is suppressed.

The first surface (22F) is excellent in flatness. When the laser (L) is irradiated to the first surface (22F), the laser (L) is unlikely to be diffusely reflected. When each of the first openings (26F) is formed, a focus position of the laser (L) is likely to match. Openings for via conductors with small diameters can be formed. The diameters of the openings for the via conductors are substantially equal to each other. For example, openings for via conductors having diameters of 15μ m or more and 35μ m or less can be formed. The diameters are measured on the first surface (22F).

FIG. 3H illustrates an inner wall surface (27Fb) of each of the first openings (26F) after the laser irradiation. The inner wall surface (27Fb) is formed of the resin 80 and the inorganic particles 90 protruding from the resin 80. In order to control a shape of the inner wall surface, the inner wall surface (27Fb) after the laser irradiation is treated. It is preferable to selectively remove the inorganic particles 90 protruding from the resin 80. As a result, the first inorganic particles 91 are formed from the inorganic particles 90. For example, the inorganic particles 90 protruding from the resin 80 are selectively removed by treating the inner wall surface (27Fb) after the laser irradiation with a chemical. Or, the inorganic particles 90 protruding from the resin 80 are selectively removed by treating the inner wall surface (27Fb) after the laser irradiation with plasma. The selectively removing includes that an etching rate of the inorganic particles 90 is greater than an etching rate of the resin 80. For example, a difference in etching rate between the two is 10 or more times. Or, the difference in etching rate between the two is 50 or more times. Or, the difference in etching rate between the two is 100 or more times. By treating the inner wall surface (27Fb) after the laser irradiation, the first inorganic particles 91 having the flat parts (91a) (see FIG. 2) are obtained. By controlling conditions for treating the inner wall surface (27Fb) after the laser irradiation, the shape of the inner wall surface (27Fb) can be controlled. Examples of the conditions are a temperature, a concentration, a time, a type of gas, and a pressure. The etching rate of the inorganic particles 90 and the etching rate of the resin are controlled.

By irradiating the first resin insulating layer (20F) with the laser (L), some of the second inorganic particles 92 embedded in the resin 80 form the inner wall surface (27Fb) after the laser irradiation. The second inorganic particles 92 forming the inner wall surface (27Fb) after the laser irradiation are each formed of a protruding portion (P) protruding from the resin 80 and a portion (E) embedded in the resin 80. The inner wall surface (27Fb) after the laser irradiation is treated. For example, the inner wall surface (27Fb) is treated with plasma of a gas containing tetrafluoromethane. The protruding portions (P) are selectively removed and the inner wall surface (27F) of the embodiment (FIGS. 1 and 2) is formed. The first inorganic particles 91 are formed from the second inorganic particles 92. By selectively removing the protruding portions (P), the first inorganic particles 91 having the flat parts (91a) are formed. The flat parts (91a) are flat surfaces. When the second inorganic particles 92 having spherical shapes are cut along a flat surface, the shapes of the first inorganic particles 91 are obtained. The inner wall surface (27F) is formed of the flat parts (91a) and the surface (80a) of the resin 80, and the exposed surfaces (91b) of the flat parts (91a) and the surface (80a) of the resin 80 are substantially positioned on the same flat surface. For example, when the seed layer (30Fa) is formed on the inner wall surface (27Fb) by sputtering, the protruding portions (P) inhibit growth of a sputtered film. For example, a continuous seed layer (30Fa) is not formed on the inner wall surface (27Fb). Or, the thickness of the seed layer (30Fa) is increased. A fine conductor circuit cannot be formed. In the embodiment, the projecting portions (P) are removed. The thickness of the seed layer (30Fa) formed by sputtering can be reduced. Even when the seed layer (30Fa) formed by sputtering is thin, a continuous seed layer (30Fa) can be obtained.

Forming the first openings (26F) includes forming the inorganic particles 90 (the second inorganic particles 92) having the protruding portions (P). The protruding portions (P) protrude from the resin 80 that forms the inner wall surface (27Fb) of each of the first openings (26F). The first inorganic particles 91 are formed by removing the protruding portions (P) of the inorganic particles 90 (the second inorganic particles 92). The inner wall surface (27F) of each of the first openings (26F) includes the exposed surfaces (91b) of the first inorganic particles 91. The exposed surfaces (91b) of the first inorganic particles 91 are formed by removing the protruding portions (P).

Obtaining the shapes of the first inorganic particles 91 by cutting the second inorganic particles 92 having spherical shapes along a flat surface includes removing the protruding portions (P) of the inorganic particles 90. The actual inner wall surface (27F) of each of the first openings (26F) is a substantially curved surface. Since the flat parts (91a) are formed by removing the protruding portions (P), the exposed surfaces (91b) of the flat parts (91a) each include a curved surface. That is, forming a common surface with the flat parts (91a) and the resin 80 includes forming the inner wall surface (27F) formed with a substantially curved surface.

The inner wall surface (27F) can have steps between the exposed surfaces (91b) of the first inorganic particles 91 and the surface (80a) of the resin 80 surrounding the first inorganic particles 91 that have the exposed surfaces (91b). The exposed surfaces (91b) are recessed from the surface (80a) of the resin 80. Or, the exposed surfaces (91b) protrude from the surface (80a) of the resin 80. The steps (distances from the exposed surfaces (91b) to the surface (80a) of the resin 80) are 5μ m or less. The steps are preferably 3μ m or less. The steps are more preferably 1.5μ m or less. Even when the steps are formed, since the steps are small, the exposed surfaces (91b) and the surface (80a) of the resin 80 form a substantially common surface.

No unevenness is formed on the inner wall surface (27F). The inner wall surface (27F) is formed smooth. By controlling the conditions for treating the inner wall surface (27Fb) after the laser irradiation, the size of the unevenness is controlled.

Insides of the first openings (26F) are cleaned. By cleaning the insides of the first openings (26F), resin residues generated when the first openings (26F) are formed are removed. The cleaning of the insides of the first openings (26F) is performed using plasma. That is, the cleaning is performed with a dry process. The cleaning includes a desmear treatment.

When the insides of the first openings (26F) are cleaned, the first surface (22F) of the resin insulating layer (20F) is covered by the protective film (50F). The first surface (22F) is not affected by the plasma. The first surface (22F) is formed only of the resin 80. No inorganic particles 90 are exposed from the first surface (22F). The first surface (22F) does not include surfaces of the inorganic particles 90. The first surface (22F) of the first resin insulating layer (20F) has no unevenness. The first surface (22F) is formed smooth.

When treating the inner wall surface (27Fb) after the laser irradiation includes cleaning the insides of the first openings (26F), cleaning the insides of the first openings (26F) can be omitted.

As illustrated in FIG. 3I, after cleaning the insides of the first openings (26F), the protective film (50F) is removed from the first resin insulating layer (20F). When treating the inner wall surface (27Fb) after the laser irradiation includes cleaning the insides of the first openings (26F), the protective film (50F) is removed from the first resin insulating layer (20F) after treating the inner wall surface (27Fb) after the laser irradiation. When the inner wall surface (27Fb) after the laser irradiation is treated, the protective film (50F) covers the first surface (22F) of the first resin insulating layer (20F). After the protective film (50F) is removed, the first surface (22F) of the first resin insulating layer (20F) is not roughened.

As illustrated in FIG. 3J, the seed layer (30Fa) is formed on the first surface (22F) of the first resin insulating layer (20F). The seed layer (30Fa) is formed by sputtering. The formation of the seed layer (30Fa) is performed with a dry process. The seed layer (30Fa) is also formed on the upper ends (8F) of the through-hole conductors 8 exposed from the first openings (26F) and on the inner wall surfaces (27F) of the first openings (26F). The seed layer (30Fa) is mainly formed of copper. The first layer (31Fa) is formed on the first surface (22F) by sputtering. The first layer (31Fa) is formed by sputtering on the inner wall surfaces (27F) exposed from the first openings (26F) and on the upper ends (8F) of the through-hole conductors 8. The second layer (31Fb) is formed on the first layer (31Fa) by sputtering.

The first layer (31Fa) of the seed layer (30Fa) is formed of an alloy containing copper, aluminum and silicon. Aluminum has high ductility and high malleability. Therefore, adhesion between the first resin insulating layer (20F) and the first layer (31Fa) is high. It is thought that, even when the first resin insulating layer (20F) expands and contracts due to heat cycles, the seed layer (30Fa) containing aluminum can follow the expansion and contraction. Even when the first surface (22F) is smooth, the seed layer (30Fa) is unlikely to peel off from the first resin insulating layer (20F). It is thought that aluminum is easily oxidized. It is thought that, when the first inorganic particles 91 are inorganic particles 90 containing oxygen, the first layer (31Fa) formed on the inner wall surface (27F) of each of the first openings (26F) adheres to the first inorganic particles 91 via the oxygen in the inorganic particles 90 forming the inner wall surface (27F). The first layer (31Fa) is strongly bonded to the inner wall surface (27F). Adhesion between the inner wall surface (27F) of each of the first openings (26F) and the first layer (31Fa) can be increased. The seed layer (30Fa) is unlikely to peel off from the inner wall surface (27F). It is preferable that the inorganic particles 90 forming the inner wall surface (27F) contain oxygen.

The first surface (22F) is excellent in flatness. When the seed layer (30Fa) is formed on the first surface (22F) by sputtering, a distance between a target and the first surface (22F) is substantially constant. A seed layer (30Fa) having a substantially uniform thickness can be formed.

A plating resist is formed on the seed layer (30Fa). The plating resist has openings for forming the first signal wiring (32F), the second signal wiring (34F), and the lands (36F) (FIG. 1).

The electrolytic plating layer (30Fb) is formed on the seed layer (30Fa) exposed from the plating resist. The electrolytic plating layer (30Fb) fills the first openings (26F). The first signal wiring (32F), the second signal wiring (34F), and the lands (36F) (FIG. 1) are formed by the seed layer (30Fa) and the electrolytic plating layer (30Fb) on the first surface (22F). The first conductor layer (30F) is formed. The first via conductors (40F) (FIG. 1) are formed by the seed layer (30Fa) and the electrolytic plating layer (30Fb) in the first openings (26F). The first via conductors (40F) connect the through-hole conductors 8 and the lands (36F). The first signal wiring (32F) and the second signal wiring (34F) form a pair wiring.

The plating resist is removed. The seed layer (30Fa) exposed from the electrolytic plating layer (30Fb) is removed. As illustrated in FIG. 3K, the first conductor layer (30F) and the first via conductors (40F) are formed at the same time.

The second resin insulating layer (120F) is formed on the first surface (22F) of the first resin insulating layer (20F) and on the first conductor layer (30F). The second conductor layer (130F) is formed on the first surface (122F) of the second resin insulating layer (120F). The second via conductors (140F) are formed in the second openings (126F) of the second resin insulating layer (120F). The second resin insulating layer (120F) is formed using the same method as the first resin insulating layer (20F). The second conductor layer (130F) is formed using the same method as the first conductor layer (30F). The second via conductors (140F) are formed using the same method as the first via conductors (40F). The wiring substrate 2 of the embodiment (FIG. 1) is obtained.

The core substrate 3 of the wiring substrate 2 of the embodiment (FIG. 1) includes the glass substrate 4. The glass substrate 4 is excellent in flatness. The first surface (22F, 22B) of the first resin insulating layer (20F, 20B) is formed of the resin 80. The first surface (22F, 22B) of the first resin insulating layer (20F, 20B) is formed only of the resin 80. The first surface (22F, 22B) of the first resin insulating layer (20F, 20B) does not include surfaces of the inorganic particles 90. The first surfaces (22F, 22B) of the first resin insulating layers (20F, 20B) are excellent in flatness and smoothness. Fine signal wirings (32F, 32B, 34F, 34B) can be formed on the first surfaces (22F, 22B) of the first resin insulating layers (20F, 20B). The first surfaces (122F, 122B) of the second resin insulating layers (120F, 120B) are similar to the first surfaces (22F, 22B) of the first resin insulating layers (20F, 20B). Therefore, fine signal wirings (132F, 132B, 134F, 134B) can be formed on the first surfaces (122F, 122B) of the second resin insulating layers (120F, 120B). The L/S of a signal wiring formed according to the embodiment is, for example, less than 5μ m/5μ. The L/S of a signal wiring is preferably 1.5μ m/1.5μ m or more and 3.5μ m/3.5μ m or less. L means a width of a signal wiring, and S means a width of a space between adjacent signal wirings.

In the embodiment, the first layer formed on the inner wall surface is formed by sputtering. The resin insulating layer on the glass substrate 4 is unlikely to warp. Gaps that inhibit growth of a sputtered film are unlikely to occur between the resin 80 forming the inner wall surface of each of the openings for the via conductors and the first inorganic particles. The inner wall surface of each of the openings is unlikely to have large undulation or large unevenness. Even when the sputtered film on the inner wall surface has a small thickness, a continuous sputtered film can be formed.

The inner wall surface 27 of each of the openings (the first openings and the second openings) for the via conductors is formed of the resin 80 and the exposed surfaces (91b) of the flat parts (91a) of the first inorganic particles 91. It is thought that, when the first layer is formed, particles forming the sputtered film adhere to the first inorganic particles 91 on the inner wall surface. It is thought that the particles forming the sputtered film are not embedded in the first inorganic particles 91. A thin and continuous seed layer can be formed on the inner wall surface. According to the embodiment, a thin and continuous seed layer can be formed on the first surface and the inner wall surface. When the seed layer is removed, an etching amount is small. Therefore, an etching amount of the electrolytic plating layer is small. A signal wiring has a width as designed. Fine signal wirings can be formed. A high quality wiring substrate 2 is provided.

In the wiring substrate 2 (FIG. 1) of the embodiment, the first surface (22F, 22B) of the first resin insulating layer (20F, 20B) is formed of the resin 80. No inorganic particles 90 are exposed from the first surface (22F, 22B). No unevenness is formed on the first surface (22F, 22B). An increase in standard deviation of a relative permittivity in a portion near the first surfaces (22F, 22B) of the first resin insulating layers (20F, 20B) is suppressed. The relative permittivity of the first surfaces (22F, 22B) does not significantly vary depending on a location. Even when the first signal wiring (32F, 32B) and the second signal wiring (34F, 34B) are in contact with the first surface (22F, 22B), a difference in propagation speed of an electrical signal between the first signal wiring (32F, 32B) and the second signal wiring (34F, 34B) can be reduced. Therefore, in the wiring substrate 2 of the embodiment, noise is suppressed. Even when a logic IC is mounted on the wiring substrate 2 of the embodiment, data transmitted via the first signal wiring (32F, 32B) and data transmitted via the second signal wiring (34F, 34B) arrive at the logic IC substantially without delay. Malfunction of the logic IC can be suppressed. Even when a length of the first signal wiring (32F, 32B) and a length of the second signal wiring (34F, 34B) are 5 mm or more, a difference in the propagation speed between the two can be reduced. Even when the length of the first signal wiring (32F, 32B) and the length of the second signal wiring (34F, 34B) are 10 mm or more and 20 mm or less, malfunction of the logic IC can be suppressed. The first surfaces (122F, 122B) of the second resin insulating layers (120F, 120B) are similar to the first surfaces (22F, 22B) of the first resin insulating layers (20F, 20B). Therefore, the first signal wirings (132F, 132B) and the second signal wirings (134F, 134B) have similar effects as the first signal wirings (32F, 32B) and the second signal wirings (34F, 34B). A high quality wiring substrate 2 is provided.

### First Alternative Example

In a first alternative example according to an embodiment of the present invention, the conditions for treating the inner wall surface (27Fb) after the laser irradiation are controlled. Therefore, as illustrated in FIG. 4, the flat parts (91a) and the surface (80a) of the resin 80 that forms the inner wall surface (27F) form substantially the same flat surface. FIG. 4 is an enlarged cross-sectional view illustrating the inner wall surface (27F) after the treatment. Distances between the exposed surfaces (91b) of the flat parts (91a) and the surface (80a) of the resin 80 are 5μ m or less. Therefore, even when there are gaps 100 between the first inorganic particles 91 and the resin 80 formed around the first inorganic particles 91, the seed layer (30Fa) can be formed in the gaps 100. In this case, the seed layer (30Fa) is formed on the inner wall surface (27F) and in the gaps 100. When distances of the exposed surfaces (91b) of the flat parts (91a) from bottoms of the gaps 100 are 5μ m or less, the seed layer (30Fa) formed by sputtering is unlikely to peel off from the inner wall surface (27F). The distances between the exposed surfaces (91b) of the flat parts (91a) and the surface (80a) of the resin 80 (widths of the gaps 100) are preferably 3μ m or less. The distances (depths of the gaps 100) between the flat parts (91a) and the bottoms of the gaps 100 are preferably 3μ m or less. Variation in the thickness of the seed layer (30Fa) on the inner wall surface (27F) can be reduced.

### Second Alternative Example

In a second alternative example according to an embodiment of the present invention, the specific metal contained in the alloy forming the first layer is at least one of nickel, zinc, gallium, silicon, and magnesium.

### Third Alternative Example

In a third alternative example according to an embodiment of the present invention, the alloy forming the first layer does not contain carbon.

### Fourth Alternative Example

In a fourth alternative example according to an embodiment of the present invention, the alloy forming the first layer does not contain oxygen.

### Modified Examples

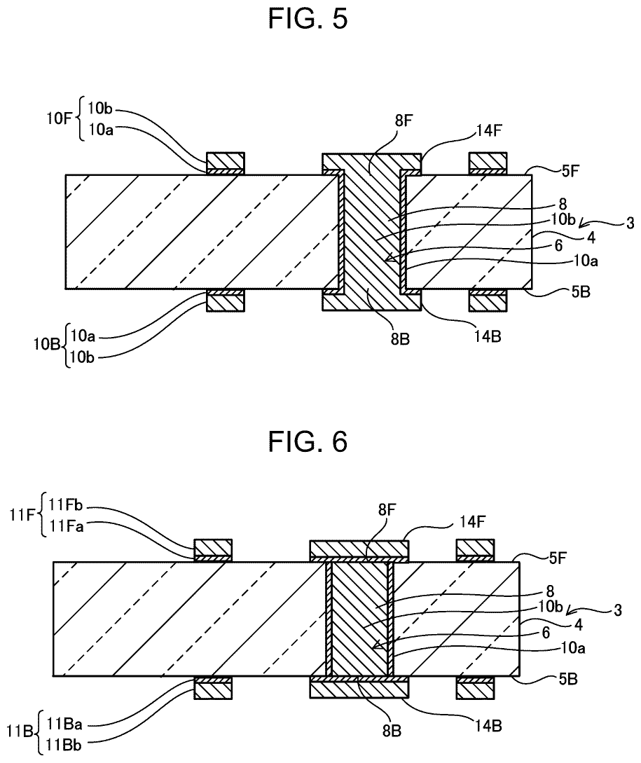

Similar to the embodiment, wiring substrates of modified examples each include a core substrate 3, a front side build-up layer (300F), and a back side build-up layer (300B). The core substrate 3 of the embodiment is different from the core substrates 3 of the modified examples. The front side build-up layer (300F) of the embodiment is the same as the front side build-up layer (300F) of each of the modified examples. The back side build-up layer (300B) of the embodiment is the same as the back side build-up layer (300B) of each of the modified examples. Cross-sections of the core substrates 3 of the modified examples are respectively illustrated in FIGS. 5 and 6. As illustrated in FIGS. 5 and 6, the core substrates 3 of the modified examples respectively have conductor layers (10F, 11F) on the front surface (5F) of the glass substrate 4. The conductor layers (10F, 11F) each include lands (14F) covering the upper ends (8F) of the through-hole conductors 8. Further, the core substrates 3 of the modified examples respectively have conductor layers (10B, 11B) on the back surface (5B) of the substrate 4. The conductor layers (10B, 11B) each include lands (14B) covering the lower ends (8B) of the through-hole conductors 8. The lands (14F) and the lands (14B) are electrically connected by the through-hole conductors 8. The core substrate 3 of the embodiment has no conductor layer on the front surface (5F) and no conductor layer on the back surface (5B).

In the modified examples, the front side resin insulating layer (resin insulating layer directly above the core substrate) forming the front side build-up layer (300F) is formed on the conductor layer (10F, 11F) and the front surface (5F). The resin insulating layer (first resin insulating layer (20F)) directly above the core substrate has openings (first openings (26F)) for via conductors reaching the lands (14F). Via conductors (first via conductors (40F)) similar to those of the embodiment are formed in the openings for via conductors. Since the via conductors penetrating the resin insulating layer directly above the core substrate reach the lands (14F), the seed layer (first layer (31Fa)) forming the via conductors is in contact with upper surfaces of the lands (14F) and inner wall surfaces of the openings. The via conductors penetrating the resin insulating layer directly above the core substrate are electrically connected to the through-hole conductors 8 via the lands (14F).

In the modified examples, the back side resin insulating layer (resin insulating layer directly below the core substrate) forming the back side build-up layer (300B) is formed on the conductor layer (10B, 11B) and the back surface (5B). The resin insulating layer (first resin insulating layer (20B)) directly below the core substrate has openings (first openings) for via conductors reaching the lands (14B). Via conductors (first via conductors (40B)) similar to those of the embodiment are formed in the openings for via conductors. Since the via conductors penetrating the resin insulating layer directly below the core substrate reach the lands (14B), the seed layer forming the via conductors is in contact with upper surfaces of the lands (14B) and inner wall surfaces of the openings. The via conductors penetrating the resin insulating layer directly below the core substrate are electrically connected to the through-hole conductors 8 via the lands (14B).

### Method for Manufacturing Wiring Substrates of Modified Examples

The core substrate 3 illustrated in FIG. 5 is a core substrate 3 of a first example. A method for manufacturing the core substrate 3 of the first example is described below. An intermediate substrate illustrated in FIG. 3D is prepared. The conductor layer (10F) is formed on the front surface (5F) using a subtractive method. The conductor layer (10B) is formed on the back surface (5B). The core substrate 3 of the first example of the modified examples is obtained.

The conductor layer (10F) is formed of the seed layer (10a) and the electrolytic plating layer (10b) on the seed layer (10a). The conductor layer (10B) is formed of the seed layer (10a) and the electrolytic plating layer (10b) on the seed layer (10a). The seed layer (10a) is formed by electroless plating. The seed layer (10a) forming the conductor layer (10F), the seed layer (10a) forming the conductor layer (10B), and the seed layer (10a) forming the through-hole conductors 8 are common. The electrolytic plating layer (10b) forming the conductor layer (10F), the electrolytic plating layer (10b) forming the conductor layer (10B), and the electrolytic plating layer (10b) forming the through-hole conductors 8 are common. The conductor layers (10F, 10B) and the through-hole conductors 8 are formed at the same time. The through-hole conductors 8 and the lands (14F, 14B) are formed at the same time. The through-hole conductors 8 and the lands (14F, 14B) are integrally formed. There is no seed layer between the upper ends (8F) and the lands (14F). There is no seed layer between the lower ends (8B) and the lands (14B).

The core substrate 3 illustrated in FIG. 6 is a core substrate 3 of a second example. A method for manufacturing the core substrate 3 of the second example is described below. An intermediate substrate illustrated in FIG. 3E is prepared. Seed layers (11Fa, 11Ba) are respectively formed on the front surface (5F) and the back surface (5B). The seed layers (11Fa, 11Ba) are formed by electroless plating. It is also possible that the seed layers (11Fa, 11Ba) are formed by sputtering. The seed layer (11Fa) covers the front surface (5F) of the substrate 4 and the upper ends (8F) of the through-hole conductors 8. The seed layer (11Ba) covers the back surface (5B) of the substrate 4 and the lower ends (8B) of the through-hole conductors 8. Electrolytic plating layers (11Fb, 11Bb) are respectively formed on the seed layers (11Fa, 11Ba). After that, the conductor layers (11F, 11B) are formed using a subtractive method. The core substrate 3 of the second example of the modified examples is obtained.

The conductor layer (11F) is formed of the seed layer (11Fa) and the electrolytic plating layer (11Fb) on the seed layer (11Fa). The conductor layer (11B) is formed of the seed layer (11Ba) and the electrolytic plating layer (11Bb) on the seed layer (11Ba). The seed layer (11Fa) is formed on the front surface (5F) of the substrate 4. The seed layer (11Fa) covers the upper ends (8F) of the through-hole conductors 8. The seed layer (11Ba) is formed on the back surface (5B) of the substrate 4. The seed layer (11Ba) covers the lower ends (8B) of the through-hole conductors 8. The seed layers (11Fa, 11Ba) are formed by electroless plating. It is also possible that the seed layers (11Fa, 11Ba) are formed by sputtering. The seed layers (11Fa, 11Ba) that respectively form the conductor layers (11F, 11B) and the seed layer (10a) that forms the through-hole conductors 8 are different from each other. The electrolytic plating layers (11Fb, 11Bb) that respectively form the conductor layers (11F, 11B) and the electrolytic plating layer (10b) that forms the through-hole conductors 8 are different from each other. The conductor layers (11F, 11B) and the through-hole conductors 8 are separately formed. In the second example, the seed layer (11Fa) forming the lands (14F) exists between the electrolytic plating layer (10b) forming the upper ends (8F) and the electrolytic plating layer (11Fb) forming the lands (14F). The seed layer (11Ba) forming the lands (14B) exists between the electrolytic plating layer (10b) forming the lower ends (8B) and the electrolytic plating layer (11Bb) forming the lands (14B). In contrast, in the first example (FIG. 5), the electrolytic plating layer (10b) forming the upper ends (8F) and the electrolytic plating layer (10b) forming the lands (14F) are continuous. The electrolytic plating layer (10b) forming the lower ends (8B) and the electrolytic plating layer (10b) forming the lands (14B) are continuous.

The front side build-up layer (300F) and back side build-up layer (300B) are formed on each of the core substrates 3 of the modified examples in the same way as the embodiment.

In the present specification, the term “flat surface” is used with respect to the shape of the inner wall surface, the shapes of the flat parts (91a), and the shapes of the first inorganic particles 91. The meaning of the “flat surface” used with respect to these is illustrated in FIGS. 1 and 2. That is, in FIGS. 1 and 2, the inner wall surface is drawn substantially straight. The shape of the inner wall surface in FIGS. 1 and 2 is substantially a straight line. The term “flat surface” in the present specification includes a substantially straight line illustrated in a cross section. As illustrated in the cross sections of the first inorganic particles 91 in FIGS. 1 and 2, in a cross section, cutting along a flat surface includes cutting along a straight line. The term “flat surface” in the present specification does not mean a perfect flat surface but includes a substantially flat surface. A substantially flat surface may include small unevenness.

In Japanese Patent Application Laid-Open Publication No. 2015-133473, light transmittance of a first insulating layer formed of a glass material is controlled. As an example of a method for controlling the light transmittance, Japanese Patent Application Laid-Open Publication No. 2015-133473 describes that a coloring agent is contained in the first insulating layer. It is thought difficult for the first insulating layer formed of a glass material to uniformly contain a coloring agent.

A wiring substrate according to an embodiment of the present invention includes: a core substrate that has a substrate formed of glass, a through hole penetrating the substrate, and a through-hole conductor formed in the through hole; a resin insulating layer that is formed on the core substrate, and has a first surface, a second surface on the opposite side with respect to the first surface, and an opening for a via conductor extending from the first surface to the second surface; a first conductor layer that is formed on the first surface of the resin insulating layer; and a via conductor that is formed in the opening and is electrically connected to the through-hole conductor. The first conductor layer and the via conductor are formed of a seed layer and an electrolytic plating layer formed on the seed layer. The seed layer is formed by sputtering. The resin insulating layer is formed of inorganic particles and a resin. The inorganic particles include first inorganic particles forming an inner wall surface of the opening and second inorganic particles embedded in the resin insulating layer, and shapes of the first inorganic particles are different from shapes of the second inorganic particles.

In a wiring substrate according to an embodiment of the present invention, the core substrate includes the glass substrate. The glass substrate is excellent in flatness. Therefore, the first surface of the resin insulating layer is excellent in flatness. The first surface is excellent in smoothness. Fine signal wirings can be formed on the first surface of the resin insulating layer. Further, in the embodiment, the seed layer formed on the inner wall surface is formed by sputtering. The sputtered seed layer can be referred to as a sputtered film. The resin insulating layer on the glass substrate is unlikely to warp. Gaps that inhibit growth of a sputtered film are unlikely to occur between the resin forming the inner wall surface of the opening for the via conductor and the first inorganic particles. The inner wall surface of the opening is unlikely to have large undulation or large unevenness. Even when the sputtered film on the inner wall surface has a small thickness, a continuous sputtered film can be formed. Further, in the embodiment, the first inorganic particles form the inner wall surface of the opening. And, the shapes of the first inorganic particles are different from the shapes of the second inorganic particles embedded in the resin insulating layer. For example, the shape of the inner wall surface can be controlled by changing the shapes of the first inorganic particles. The inner wall surface is a surface in contact with the via conductor. Therefore, by controlling the shape of the inner wall surface, adhesion between the via conductor and the resin insulating layer can be increased. Therefore, by controlling the shape of the inner wall surface, the thickness of the seed layer on the inner wall surface can be reduced. Variation in the thickness of the seed layer can be reduced. Widths of conductor circuits in the first conductor layer can be close to target values.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core substrate comprising a glass substrate and a through-hole conductor formed in the glass substrate;
a resin insulating layer formed on the core substrate and comprising resin and inorganic particles;
a conductor layer formed on a surface of the resin insulating layer and comprising a seed layer and an electrolytic plating layer formed on the seed layer; and
a via conductor formed in the resin insulating layer such that the via conductor is electrically connected to the through-hole conductor formed in the glass substrate of the core substrate and includes the seed layer and electrolytic plating layer extending from the conductor layer,
wherein the conductor layer and the via conductor are formed such that the seed layer is formed by sputtering, and the resin insulating layer has an opening in which the via conductor is formed such that the inorganic particles include first particles forming an inner wall surface in the opening and second particles embedded in the resin insulating layer having shapes that are different from shapes of the first particles.

2. The wiring substrate according to claim 1, wherein the resin insulating layer is formed such that the inner wall surface in the opening includes the first particles and the resin and that the first particles have flat parts forming the inner wall surface.

3. The wiring substrate according to claim 2, wherein the resin insulating layer is formed such that the inner wall surface in the opening is consisting of the resin and the flat parts of the first particles.

4. The wiring substrate according to claim 3, wherein the resin insulating layer is formed such that the inner wall surface in the opening has substantially a common surface formed of the flat parts of the first particles and a surface of the resin.

5. The wiring substrate according to claim 3, wherein the resin insulating layer is formed such that the flat parts of the first particles have exposed surfaces forming steps between the exposed surfaces and a surface of the resin.

6. The wiring substrate according to claim 2, wherein the resin insulating layer is formed such that each of the second particles has a spherical shape.

7. The wiring substrate according to claim 2, wherein the resin insulating layer is formed such that each of the first particles has a shape obtained by cutting a sphere along a flat surface.

8. The wiring substrate according to claim 6, wherein the resin insulating layer is formed such that the first particles have shapes obtained by cutting the second particles along a flat surface.

9. The wiring substrate according to claim 1, wherein the conductor layer and the via conductor are formed such that the seed layer includes an alloy comprising copper, aluminum, and at least one metal selected from the group consisting of nickel, zinc, gallium, silicon, and magnesium.

10. The wiring substrate according to claim 9, wherein the seed layer in the conductor layer and the via conductor is formed such that the at least one metal in the alloy includes silicon.

11. The wiring substrate according to claim 9, wherein the seed layer in the conductor layer and the via conductor is formed such that a content of aluminum in the alloy is in a range of 1.0 at % to 15.0 at %.

12. The wiring substrate according to claim 9, wherein the seed layer in the conductor layer and the via conductor is formed such that the alloy includes carbon and that a content of carbon in the alloy is 50 ppm or less.

13. The wiring substrate according to claim 9, wherein the seed layer in the conductor layer and the via conductor is formed such that the alloy includes oxygen and that a content of oxygen in the alloy is 100 ppm or less.

14. The wiring substrate according to claim 2, wherein the conductor layer and the via conductor are formed such that the seed layer includes an alloy comprising copper, aluminum, and at least one metal selected from the group consisting of nickel, zinc, gallium, silicon, and magnesium.

15. The wiring substrate according to claim 14, wherein the seed layer in the conductor layer and the via conductor is formed such that the at least one metal in the alloy includes silicon.

16. The wiring substrate according to claim 9, wherein the seed layer in the conductor layer and the via conductor is formed such that a content of aluminum in the alloy is in a range of 1.0 at % to 15.0 at %.

17. The wiring substrate according to claim 9, wherein the seed layer in the conductor layer and the via conductor is formed such that the alloy includes carbon and that a content of carbon in the alloy is 50 ppm or less.

18. The wiring substrate according to claim 9, wherein the seed layer in the conductor layer and the via conductor is formed such that the alloy includes oxygen and that a content of oxygen in the alloy is 100 ppm or less.

19. A method for manufacturing a wiring substrate, comprising:
forming a core substrate comprising a glass substrate and a through-hole conductor formed in the glass substrate;
forming a resin insulating layer on the core substrate such that the resin insulating layer includes resin and inorganic particles;
forming a conductor layer on a surface of the resin insulating layer such that the conductor layer includes a seed layer and an electrolytic plating layer formed on the seed layer; and
forming a via conductor in the resin insulating layer such that the via conductor electrically connects to the through-hole conductor formed in the glass substrate of the core substrate and includes the seed layer and electrolytic plating layer extending from the conductor layer,
wherein the forming of the conductor layer and the forming of the via conductor includes forming the seed layer by sputtering, the forming of the resin insulating layer includes forming an opening in which the via conductor is formed such that the inorganic particles include first particles forming an inner wall surface in the opening and second particles embedded in the resin insulating layer having shapes that are different from shapes of the first particles, and the forming of the opening includes forming the inorganic particles having protruding portions protruding from the resin in the opening, and removing the protruding portions of the inorganic particles such that the first particles are formed.

20. The method of claim 19, wherein the protruding portions of the inorganic particles are removed such that the inner wall surface of the opening includes exposed surfaces of the first particles.
